(19) United States
(12) Patent Application Publication
(10) Pub. No.: US 2023/0354521 A1
(43) Pub. Date: Nov. 2, 2023

(54) ELECTRONIC DEVICE

(71) Applicant: Innolux Corporation, Miaoli County (TW)

(72) Inventors: Chueh-Yuan Nien, Miaoli County (TW); Chao-Chin Sung, Miaoli County (TW); Chien-Tzu Chu, Miaoli County (TW); Yu-Chien Kao, Miaoli County (TW); Li-Wei Sung, Miaoli County (TW)

(73) Assignee: Innolux Corporation, Miaoli County (TW)

(21) Appl. No.: 18/189,211

(22) Filed: Mar. 24, 2023

(30) Foreign Application Priority Data
Apr. 28, 2022 (CN) 202210460725.3

(51) Int. Cl. H05K 1/11; H05K 3/28; H05K 1/14; H05K 3/32; H05K 3/10

(52) U.S. Cl. CPC H05K 1/111; H05K 3/28; H05K 1/145; H05K 3/321; H05K 3/103

(57) ABSTRACT

Disclosed are an electronic device and another electronic device. The electronic device includes a circuit substrate, a conductive adhesive, a driving element and a first protective layer. The circuit substrate includes a connection pad. The conductive adhesive covers the connection pad. The driving element is arranged on the connection pad, and is electrically connected to the circuit substrate through the conductive adhesive. Another electronic device includes a circuit substrate, a first electronic unit, a second electronic unit, and a first protective layer. The first electronic unit is arranged on the circuit substrate and has two side walls. The second electronic unit is arranged on the circuit substrate and has two side walls. The first protective layer at least surrounds a part of both side walls of the first electronic unit and a part of both side walls of the second electronic unit.

### CROSS-REFERENCE TO RELATED APPLICATION

This application claims the priority benefit of China application serial no. 202210460725.3, filed on Apr. 28, 2022. The entirety of the above-mentioned patent application is hereby incorporated by reference herein and made a part of this specification.

### BACKGROUND

### Field of the Disclosure

The present disclosure relates to an electronic device, and more particularly, to an electronic device capable of blocking moisture or improving reflectivity.

### DESCRIPTION OF RELATED ART

Electronic devices or splicing electronic devices have been commonly used in different fields such as communication, display, vehicle or aviation. With the vigorous development of electronic devices, electronic devices are developed in the tendency of being thinner and lighter. Therefore, higher reliability or quality requirements are set for electronic devices.

### SUMMARY OF THE DISCLOSURE

The present disclosure provides an electronic device that can block moisture or improve reflectivity.

In an embodiment of the present disclosure, an electronic device includes a circuit substrate, a conductive adhesive, a driving element, and a first protective layer. The circuit substrate includes a connection pad. The conductive adhesive covers the connection pad. The driving element is arranged on the connection pad, and is electrically connected to the circuit substrate through the conductive adhesive. The first protective layer covers part of the conductive adhesive.

In an embodiment of the present disclosure, an electronic device includes a circuit substrate, a first electronic unit, a second electronic unit, and a first protective layer. The first electronic unit is arranged on the circuit substrate and has two side walls. The second electronic unit is arranged on the circuit substrate and has two side walls. The second electronic unit and the first electronic unit respectively have different functions. The first protective layer at least surrounds a part of both side walls of the first electronic unit and a part of both side walls of the second electronic unit.

### BRIEF DESCRIPTION OF THE DRAWINGS

The accompanying drawings are included to provide a further understanding of the disclosure, and are incorporated in and constitute a part of this specification. The drawings illustrate of the disclosure and, together with the description, serve to explain the principles of the disclosure.

FIG. 1A is a schematic top view of an electronic device according to an embodiment of the disclosure.

FIG. 1B is a schematic cross-sectional view of the electronic device of FIG. 1A taken along section line I-I′.

FIG. 2A is an enlarged schematic view of a region R1 of FIG. 1A.

FIG. 2B is a schematic cross-sectional view of the electronic device of FIG. 2A taken along section line II-II′.

FIG. 2C is a schematic cross-sectional view of the electronic device of FIG. 2A taken along section line III-III′.

FIG. 3A is an enlarged schematic view of a region R2 of FIG. 1A.

FIG. 3B is a schematic cross-sectional view of the electronic device of FIG. 3A taken along section line IV-IV′.

FIG. 4 is a schematic cross-sectional view of the electronic device of another embodiment of FIG. 1A taken along section line I-I′.

FIG. 5 is a schematic cross-sectional view of the electronic device according to another embodiment of FIG. 2A taken along section line II-II′.

FIG. 6A is a schematic top view of an electronic device according to another embodiment of the disclosure.

FIG. 6B is a schematic cross-sectional view of the electronic device of FIG. 6A taken along section line V-V′.

FIG. 7 is a schematic cross-sectional view of the electronic device according to another embodiment of FIG. 6A taken along section line V-V′.

### DESCRIPTION OF EMBODIMENTS

The disclosure can be understood by referring to the following detailed description in combination with the accompanying drawings. It should be noted that in order to make it easy for the reader to understand and for the simplicity of the drawings, the multiple drawings in this disclosure only depict a part of the electronic device/display device, and the specific components in the drawings are not drawn according to actual scale. In addition, the number and size of each component in the drawings are only for exemplary purpose, and are not intended to limit the scope of the disclosure.

In the following description and claims, the words “comprising” and “including” are open-ended words, and thus should be interpreted as meaning “including but not limited to . . . ”.

It should be understood that when an element or film is referred to as being “on” or “connected” to another element or film, the element or film may be directly on the other element or film or directly connected to the other element or film, or there is an intervening element or film between the two (indirectly). Conversely, when an element or film is said to be “directly” on or “directly connected” to another element or film, there is no intervening element or film between the two.

Although the terms “first”, “second”, “third” . . . may be used to describe various constituent elements, the constituent elements are not limited by the terms. This term is only used to distinguish a single constituent element from other constituent elements in the specification. The same terms may not be used in the claims, but replaced by first, second, third, . . . in the order in which the elements are recited in the claims. Therefore, in the following description, the first constituent element may be the second constituent element in the claims.

The terms “about”, “roughly”, “substantially”, and “approximately” used in the text are generally interpreted as being within 10% of a given value or range, or interpreted as being within 5%, 3%, 2%, 1%, or 0.5% of a given value or range. The quantity given here is an approximate quantity, that is, in the absence of a specific description of “about”, “roughly”, “substantially”, “approximately”, the meaning of “about”, “roughly”, “substantially”, “approximately” is still implicitly applied.

In some embodiments of the disclosure, terms such as “connected”, “interconnected”, etc., about joining and connecting, unless specifically defined, can mean that two structures are in direct contact, or that two structures are not directly in contact, where there are other structures located between the two structures. The terms of joining and connecting may also include the case where both structures are movable or both structures are fixed. In addition, the term “coupling” include any direct and indirect electrical connection means.

In some embodiments of the present disclosure, optical microscopy (OM), scanning electron microscope (SEM), film thickness profiler (a-step), ellipsometer, or other suitable methods may be adopted to measure the area, width, thickness or height of various elements, or the distance or spacing between elements. In detail, according to some embodiments, an SEM may be used to obtain an image of cross-sectional structure including an elements to be measured, and measure the area, width, thickness or height of various elements, or distance or spacing between elements.

The electronic device of the present disclosure may include, but is not limited to, a display device, a backlight device, an antenna device, a sensing device, or a splicing device. The electronic device may be a bendable or flexible electronic device. The display device may be a non-self-luminous display device or a self-luminous display device. The antenna device may be a liquid crystal antenna device or a non-liquid crystal antenna device, and the sensing device may be a sensing device for sensing capacitance, light, heat or ultrasonic waves, but not limited thereto. Electronic elements in an electronic device may include passive elements and active elements, such as capacitors, resistors, inductors, diodes, transistors, and the like. The diodes may include light emitting diodes or photodiodes. The light emitting diodes may include, for example, organic light emitting diodes (OLEDs), sub-millimeter light emitting diodes (mini LEDs), micro LEDs or quantum dot LEDs, but not limited thereto. The splicing device may be, for example, a display splicing device or an antenna splicing device, but not limited thereto. It should be noted that, the electronic device may be any arrangement or combination of the foregoing, but not limited thereto. Hereinafter, the present disclosure will be described with an electronic device.

It should be noted that, in the following embodiments, features in several different embodiments may be replaced, recombined, and mixed to complete other embodiments without departing from the spirit of the present disclosure. As long as the features of the various embodiments do not violate the spirit of the disclosure or conflict with each other, they may be mixed and matched freely.

Reference will now be made in detail to the exemplary embodiments of the present disclosure, examples of which are illustrated in the accompanying drawings. Wherever possible, the same reference numerals are used in the drawings and description to refer to the same or like parts.

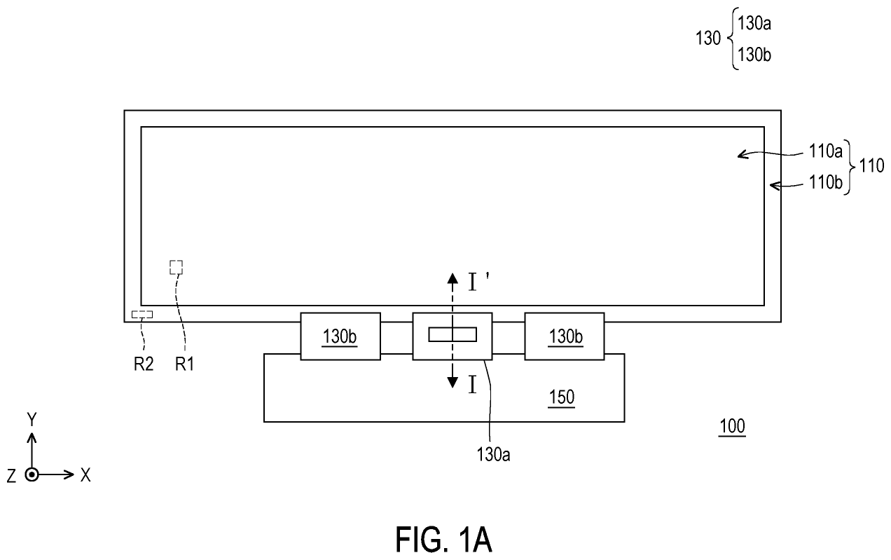

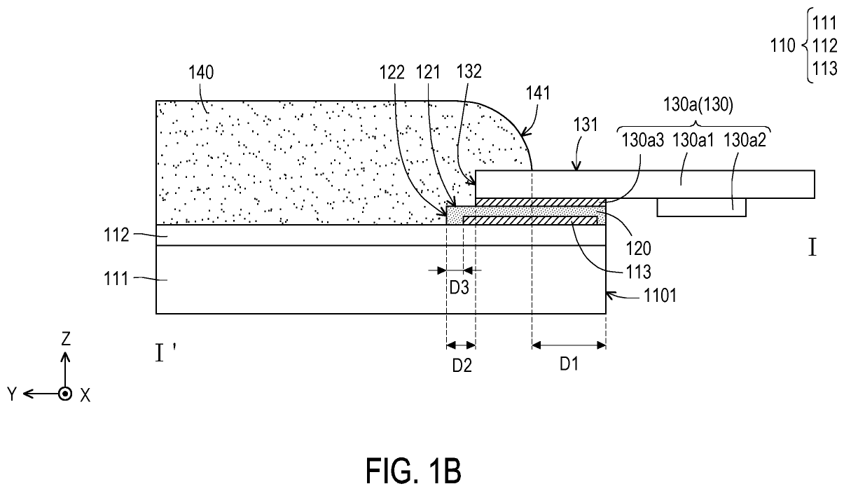

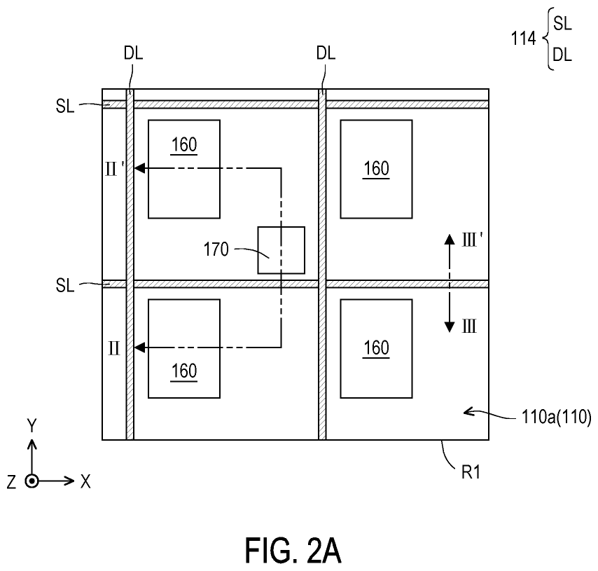

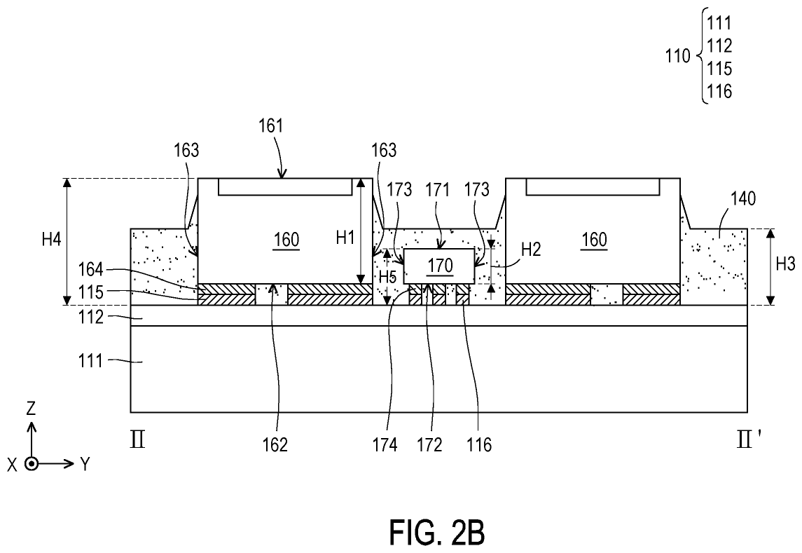

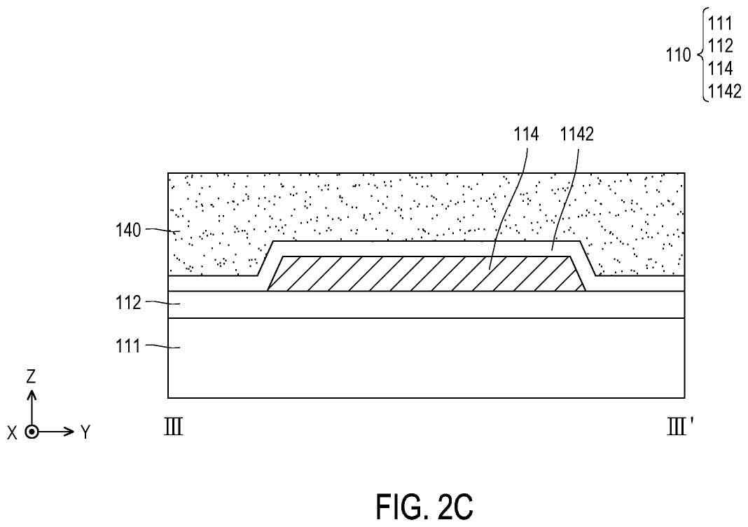

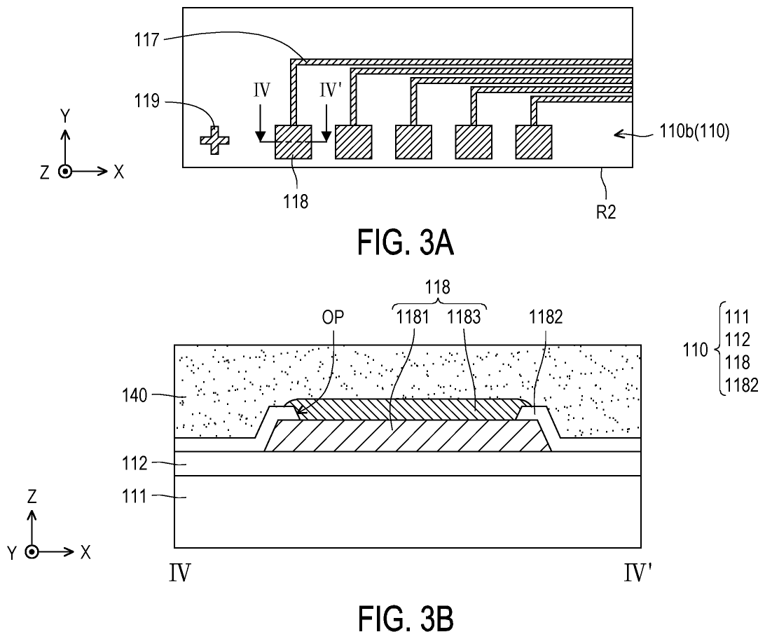

FIG. 1A is a schematic top view of an electronic device according to an embodiment of the disclosure. FIG. 1B is a schematic cross-sectional view of the electronic device of FIG. 1A taken along section line I-I′. FIG. 2A is an enlarged schematic view of a region R1 of FIG. 1A. FIG. 2B is a schematic cross-sectional view of the electronic device of FIG. 2A taken along section line II-II′. The scan line SL is not shown. FIG. 2C is a schematic cross-sectional view of the electronic device of FIG. 2A taken along section line FIG. 3A is an enlarged schematic view of a region R2 of FIG. 1A. FIG. 3B is a schematic cross-sectional view of the electronic device of FIG. 3A taken along section line IV-IV′. For clarity of illustration and convenience of description, FIG. 1A, FIG. 2A and FIG. 3A omit some elements in the electronic device 100, and FIG. 2C omits the conductive wire 114, but the disclosure is not limited thereto.

First, please refer to FIG. 1A and FIG. 1B, the electronic device 100 of this embodiment includes a circuit substrate 110, a conductive adhesive 120, a driving element 130, a first protective layer 140, and a printed circuit board 150. In this embodiment, the direction X, the direction Y and the direction Z are respectively different directions. The direction Y is, for example, the extending direction of the section line I-I′, and the direction Z is, for example, the normal direction of the circuit board 110. The direction Y is substantially perpendicular to the direction Z, and the direction Y and the direction Z are respectively substantially perpendicular to the direction X, but the disclosure is not limited thereto.

Specifically, the circuit substrate 110 has a display region 110a and a non-display region 110b adjacent to the display region 110a. In this embodiment, the non-display region 110b may be configured to surround the display region 110a, for example, but not limited thereto. The region R1 may be any region of the display region 110, and the region R2 may be any region of the non-display region 110b. In addition, the circuit substrate 110 may include a substrate 111, an insulating layer 112, a connection pad 113, and a thin film transistor (TFT) (not shown), but not limited thereto. The insulating layer 112 is a multi-layer structure, and the thin film transistor is disposed between the multi-layer structure. The insulating layer 112 is disposed on the substrate 111. The connection pad 113 is disposed on the insulating layer 112, and the connection pad 113 may be electrically connected to the thin film transistor. The connection pad 113 is located in the non-display region 110b. In this embodiment, the substrate 111 may be, for example, a rigid substrate, a flexible substrate or a combination of the foregoing. For example, the material of the substrate 111 may include glass, quartz, sapphire, ceramic, polycarbonate (PC), polyimide (PI), polyethylene terephthalate (PET), other suitable substrate materials, or a combination of the foregoing, but not limited thereto. The insulating layer 112 may be a single-layer structure or a multi-layer structure, and the material of the insulating layer 112 may include silicon nitride, silicon oxide, other suitable inorganic materials, or a combination of the foregoing, but is not limited thereto. The material of the connection pad 113 may include copper, nickel, other suitable metal materials or a combination of the foregoing, but is not limited thereto.

The conductive adhesive 120 is disposed on the connection pad 113. The conductive adhesive 120 may cover the connection pad 113. In this embodiment, the conductive adhesive 120 may cover and contact the top surface and the lateral surface of the connection pad 113, but not limited thereto. The conductive adhesive 120 may be, for example, an anisotropic conductive film (ACF), but not limited thereto.

The driving element 130 is disposed on the connection pad 113. The driving element 130 may be bonded to the connection pad 113 through the conductive adhesive 120, and the driving element 130 may be electrically connected to the circuit substrate 110 through the conductive adhesive 120. In this embodiment, the driving element 130 may cover part of the conductive adhesive 120 and expose part of the top surface 121 of the conductive adhesive 120 or the lateral edge 122 of the conductive adhesive 120, but not limited thereto. In this embodiment, the driving element 130 may include a first driving element 130a and a second driving element 130b. The first driving element 130a is, for example, a chip-on-film (COF), and the second driving element 130b is, for example, a flexible printed circuit (FPC), but not limited thereto. The first driving element 130a has a circuit board 130a1, a chip 130a2 and a pad 130a3. The circuit board 130a1 may be, for example, a flexible printed circuit board, but not limited thereto. The chip 130a2 is disposed on the circuit board 130a1. A part of the circuit board 130a1 and the chip 130a2 do not overlap with the circuit substrate 110 in the normal direction (i.e., the direction Z) of the circuit substrate 110. The pad 130a3 is disposed on the circuit board 130a1, so that the first driving element 130a may be bonded to the conductive adhesive 120 through the pad 130a3.

The first protective layer 140 is disposed on the insulating layer 112 in the circuit substrate 110 and further disposed on the driving element 130. The first protective layer 140 may also cover part of the driving element 130, part of the conductive adhesive 120 not covered by the driving element 130, and part of the circuit substrate 110. In this embodiment, the first protective layer 140 may cover and contact part of the top surface 131 of the driving element 130, the lateral edge 132 of the driving element 130 (i.e., the lateral edge of the driving element 130 close to the first protective layer 140), part of the top surface 121 of the conductive adhesive 120, the lateral edge 122 of the conductive adhesive 120 (i.e., the lateral edge of the conductive adhesive 120 close to the first protective layer 140) and part of the circuit substrate 110, but not limited thereto.

Generally speaking, the method of using an insulating layer (such as an inorganic film layer) to protect metal materials is likely to cause paths such as pin holes and cracks for moisture to enter due to subsequent cutting processes or thermal processes, which in turn cause metal materials to corrode due to the intrusion of moisture from pin holes or cracks. In addition, although solder resist (such as green paint, acrylic resin or epoxy resin) or photoresist is generally used to protect the metal material, the thickness of the solder resist or the photoresist applied by screen printing or spraying process is relatively thin (for example, less than 10 microns, but not limited to), and the moisture cannot be effectively blocked. However, the thickness of the first protective layer 140 formed by the coating process in this embodiment is relatively thick (for example, greater than 40 microns, but not limited thereto), so the problem of corrosion of metal materials due to intrusion of moisture may be effectively solved. Therefore, in this embodiment, through the configuration that the first protective layer 140 covers and contacts part of the top surface 131 of the driving element 130, the lateral edge 132 of the driving element 130 (including the lateral edge of the pad 130a3), part of the top surface 121 of the conductive adhesive 120, the lateral edge 122 of the conductive adhesive 120, and the insulating layer 112 of the circuit substrate 110, it is possible to protect the conductive adhesive 120 (i.e., reduce the exposure of the conductive adhesive 120) and the pad 130a3 on the lower surface of the driving element 130, so as to prevent the intrusion of moisture from corroding the connection pad 113 and the pad 130a3 on the lower surface of the driving element 130, thereby having the effect of blocking moisture.

In addition, by using the first protective layer 140 to cover and contact part of the top surface 131 of the driving element 130, the lateral edge 132 of the driving element 130 (including the lateral edge of the pad 130a3), part of the top surface 121 of the conductive adhesive 120, the lateral edge 122 of the conductive adhesive 120, and the insulating layer 112 of the circuit substrate 110, it is possible to improve the bonding strength of bonding the driving element 130 to the conductive adhesive 120 and the bonding strength of bonding the conductive adhesive 120 to the circuit substrate 110. That is, by disposing the first protective layer 140, the bonding strength of bonding the driving element 130 to the connection pad 113 (circuit substrate 110) may be improved, so that the driving element 130 and the connection pad 113 (or the circuit substrate 110) are not easily peeled off due to external force.

In addition, compared with the reflectivity of solder resist or photoresist (for example, less than 75%, but not limited to), the first protective layer 140 of this embodiment may have a higher reflectivity. Therefore, when the first protective layer 140 is used to cover part of the circuit substrate 110, the reflectivity (or reflection effect) of the circuit substrate 110 may be improved, thereby improving the effective utilization of the light source. In this embodiment, the reflectivity of the first protective layer 140 may be, for example, greater than or equal to 90%, but not limited thereto. In addition, in this embodiment, the material of the first protective layer 140 may include silicon-based colloid, other materials having the effect of blocking moisture and improving reflectivity, or a combination of the foregoing, but not limited thereto.

In this embodiment, the lateral edge 141 of the first protective layer 140 (i.e., the lateral edge of the first protective layer 140 adjacent to the edge 1101 of the circuit substrate 110) contacts the top surface 131 of the driving element 130, and there is a distance D1 between a position where the lateral edge 141 and the top surface 131 are in contact and the edge 1101 of the circuit substrate 110, but not limited thereto. The distance D1 is, for example, the horizontal distance measured along the direction Y and between the lateral edge 141 of the first protective layer 140 and the edge 1101 of the circuit substrate 110. In some embodiments, the lateral edge of the first protective layer 140 adjacent to the edge 1101 of the circuit substrate 110 may also be substantially aligned with the edge 1101 (not shown) of the circuit substrate 110.

In addition, in this embodiment, there is a distance D2 between the lateral edge 122 of the conductive adhesive 120 close to the first protective layer 140 and the lateral edge 132 of the driving element 130 close to the first protective layer 140, and there is a distance D3 between the lateral edge 122 of the conductive adhesive 120 and the connection pad 113. The distance D2 is, for example, the horizontal distance measured along the direction Y and between the lateral edge 122 of the conductive adhesive 120 and the lateral edge 132 of the driving element 130, and the distance D3 is, for example, the minimum horizontal distance measured along direction Y and between the lateral edge 122 of the conductive adhesive 120 and the connection pad 113. In this embodiment, the distance D3 is, for example, greater than 0 millimeters (mm) and less than or equal to the distance D2 (i.e., 0 mm<D3≤D2), but not limited thereto. When the distance D3 is greater than 0 mm, it may be ensured that the conductive adhesive 120 completely covers the connection pad 113. In this embodiment, the distance D2 is, for example, greater than 0 mm and less than or equal to 5 mm (0 mm<D2≤5 mm), which can ensure that the conductive adhesive 120 completely contacts the connection pad 130a3 on the driving element 130a. In addition, the driving element 130a may be bonded with the connection pad 113 to reduce the problem of abnormal resistance value.

The printed circuit board 150 and the circuit substrate 110 are respectively disposed on opposite sides of the driving element 130. In some embodiments, the printed circuit board 150 does not overlap with the circuit substrate 110 in the normal direction (i.e., the direction Z) of the circuit substrate 110. In other embodiments, the printed circuit board 150 may be bent to the back of the circuit substrate 110, so that the printed circuit board 150 overlaps with the circuit substrate 110 in the normal direction (i.e., the direction Z) of the circuit substrate 110. The printed circuit board 150 may be electrically connected to the circuit substrate 110 through the driving element 130.

Next, referring to FIG. 2A to FIG. 2C, the electronic device 100 further includes a first electronic unit 160 and a second electronic unit 170, and the circuit substrate 110 further includes a conductive wire 114, a connection pad 115 and a connection pad 116.

Specifically, as shown in FIG. 2A and FIG. 2B, the first electronic unit 160 is disposed on the display region 110a of the circuit substrate 110, the second electronic unit 170 is disposed on the display region 110a of the circuit substrate 110, and the first electronic unit 160 and the second electronic unit 170 respectively have different functions. The first electronic unit 160 and the second electronic unit 170 may be electrically connected to each other through the circuit substrate 110. The height H1 of the first electronic unit 160 may be greater than the height H2 of the second electronic unit 170. The height H1 is, for example, the maximum height of the first electronic unit 160 measured along the direction Z, and the height H2 is, for example, the maximum height of the second electronic unit 170 measured along the direction Z. In some embodiments, the height of the first electronic unit 160 may be smaller than the height of the second electronic unit 170, but is not limited thereto. In this embodiment, the first electronic unit 160 may be, for example, a light-emitting diode, and the second electronic unit 170 may be, for example, a driver or a passive element, but not limited thereto.

The first electronic unit 160 has an upper surface 161 and a lower surface 162 opposite to each other, two side walls 163 connecting the upper surface 161 and the lower surface 162, and a pad 164 disposed on the lower surface 162. The pad 164 of the first electronic unit 160 may be bonded to the connection pad 115 on the insulating layer 112, and the first electronic unit 160 may be electrically connected to the circuit substrate 110 through the pad 164 and the connection pad 115.

The second electronic unit 170 has an upper surface 171 and a lower surface 172 opposite to each other, two side walls 173 connecting the upper surface 171 and the lower surface 172, and a pad 174 disposed on the lower surface 172. The pad 174 of the second electronic unit 170 may be bonded to the connection pad 116 on the insulating layer 112, and the second electronic unit 170 may be electrically connected to the circuit substrate 110 through the pad 174 and the connection pad 116. In this embodiment, the materials of the pad 164, the pad 174, the connection pad 115 and the connection pad 116 may include copper, nickel, other suitable metal materials or a combination of the foregoing, but are not limited thereto. In some embodiments, a conductive bump made of tin, lead or other suitable metal materials or a combination of the foregoing is further included between the pad 164 and the connection pad 115 and between the pad 174 and the connection pad 116, so that the pad and the connection pad are electrically connected, but the disclosure is not limited thereto.

In this embodiment, the first protective layer 140 is disposed on the circuit substrate 110 and further disposed on the insulating layer 112. The height H3 of the first protective layer 140 (i.e., the distance from the insulating layer 112 on the circuit substrate 110 to the top surface of the first protective layer 140) is less than the height H4 between the upper surface 161 of the first electronic unit 160 and the insulating layer 112, and is greater than the height H5 between the upper surface 171 of the second electronic unit 170 and the insulating layer 112. Since the first protective layer 140 may at least surround part of the two side walls 163 of the first electronic unit 160, at least surround part of the two side walls 173 of the second electronic unit 170, and cover the upper surface 171 of the second electronic unit 170, the first protective layer 140 may protect the connection pad 115 and the connection pad 116, thereby reducing the problem of moisture intrusion and corrosion of the connection pad 115 (or the connection pad 116), and achieving the effect of blocking moisture. Additionally, by using the first protective layer 140 to surround and contact part of the two side walls 163 of the first electronic unit 160 (or part of the two side walls 173 of the second electronic unit 170), the pad 164 (or the pad 174), and the connection pad 115 (or the connection pad 116), it is possible to improve the bonding strength of bonding the first electronic unit 160 (or the second electronic unit 170) to the circuit substrate 110. That is to say, by disposing the first protective layer 140, the bonding strength of bonding the first electronic unit 160 (or the second electronic unit 170) to the connection pad 115 (the circuit substrate 110) may be improved, so that the first electronic unit 160 (or the second electronic unit 170) and the circuit substrate 110 are not easily peeled off due to external force.

In this embodiment, since the cohesive force of the first protective layer 140 is much smaller than the adsorption force of the first protective layer with respect to the first electronic unit 160 (i.e., capillary phenomenon), the first protective layer 140, at a position close to the first electronic unit 160, may further be adsorbed upward (i.e., toward the direction away from the circuit substrate 110) on other part of the two side walls 163. Moreover, in this embodiment, since the first protective layer 140 may be adsorbed on other part of the two side walls 163, the bonding strength of bonding the first electronic unit 160 to the connection pad 115 (circuit substrate 110) may be improved. In this embodiment, the reflectivity of the first protective layer 140 to visible light may be, for example, greater than or equal to 90%, but not limited thereto. Furthermore, in this embodiment, the material of the first protective layer 140 may include silicon-based colloid, other materials having the effect of blocking moisture and improving reflectivity, or a combination of the foregoing, but not limited thereto.

In this embodiment, although the height H3 of the first protective layer 140 may be less than the height H4 between the upper surface 161 of the first electronic unit 160 and the insulating layer 112 and greater than the height H5 between the upper surface 171 of the second electronic unit 170 and the insulating layer 112, the present disclosure does not limit the height of the first protective layer 140. For example, in some embodiments, the height of the first protective layer may also be substantially equal to the height between the upper surface of the first electronic unit and the insulating layer and greater than the height (not shown) between the upper surface of the second electronic unit and the insulating layer.

Then, as shown in FIG. 2A and FIG. 2C, the circuit substrate 110 further includes a conductive wire 114. The conductive wire 114 is disposed on the insulating layer 112 of the display region 110a, and the insulating layer 1142 is disposed on the conductive wire 114 to cover the conductive wire 114 and part of the insulating layer 112. The insulating layer 1142 may be a single-layer structure or a multi-layer structure, and the material of the insulating layer 1142 may include organic materials, inorganic materials (e.g., silicon nitride, silicon oxide) or combinations thereof, but not limited thereto. The material of the conductive wire 114 may include metal, but is not limited thereto. In this embodiment, the conductive wire 114 may include one of a signal line (not shown), a scan line SL, a data line DL, and a power line (not shown). The conductive wire 114 may be electrically connected to at least one of the first electronic unit 160 and the second electronic unit 170. In addition, in this embodiment, since the first protective layer 140 may cover the conductive wire 114 or further contact the insulating layer 1142 on the conductive wire 114, the conductive wire 114 may be protected to reduce the corrosion of the conductive wire 114 caused by moisture intrusion problem, and the effect of blocking moisture may be achieved.

In some embodiments, a buffer layer (not shown) may further be disposed between the first protective layer 140 and the insulating layer 1142, and the buffer layer may include a color filter layer, a photoresist, or a hard coating, but the disclosure is not limited thereto.

Next, referring to FIG. 3A to FIG. 3B, the circuit substrate 110 further includes a conductive wire 117, a test pad 118 and an alignment mark 119. Specifically, the conductive wire 117, the test pad 118 and the alignment mark 119 are disposed on the insulating layer 112 of the non-display region 110b, and the conductive wire 117 may be electrically connected to the corresponding test pad 118. The cross-sectional schematic view of the conductive wire 117 may be substantially as shown in FIG. 2C, so the details are not repeated here. The test pad 118 has a metal layer 1181 and a metal layer 1183. The insulating layer 1182 is disposed on the metal layer 1181 to cover part of the insulating layer 112. The insulating layer 1182 has an opening OP to expose a part of the metal layer 1181. The metal layer 1183 is disposed on the insulating layer 1182 and in the opening OP. In this embodiment, the insulating layer 1182 may be a single-layer structure or a multi-layer structure, and the material of the insulating layer 1182 may include organic materials, inorganic materials (e.g., silicon nitride, silicon oxide) or a combination of the foregoing, but not limited thereto. Moreover, in the present embodiment, since the first protective layer 140 may cover the test pad 118, the test pad 118 may be protected, so as to reduce the problem of corrosion of the test pad 118 caused by moisture intrusion, and the effect of blocking moisture may be achieved.

In some embodiments, a buffer layer (not shown) may be further disposed between the first protective layer 140 and part of the insulating layer 1182 or between the first protective layer 140 and part of the metal layer 1183, and the buffer layer may include, but not limited to, a color filter layer, a photoresist or a hard coating, but not limited thereto. In some embodiments, the test pad 118 may not include the metal layer 1183 depending on the requirement, so that the first protective layer 140 may also be disposed in the opening OP (not shown) of the insulating layer 1182 and optionally include a buffer layer.

In this embodiment, a schematic cross-sectional view of the alignment mark 119 may be substantially as shown in FIG. 2C. The insulating layer is disposed on the alignment mark 119 to cover the alignment mark 119 and part of the insulating layer 112. The first protective layer 140 may cover the alignment mark 119 or further contact the insulating layer on the alignment mark 119. In some embodiments, a buffer layer (not shown) may further be disposed between the first protective layer 140 and the insulating layer on the alignment mark 119, and the buffer layer may include a color filter layer, a photoresist resist, or a hard coating, but not limited thereto. In some embodiments, the shape of the alignment mark 119 may be, for example, a cross, a circle, a triangle, or other suitable geometric shapes, but not limited thereto.

Other examples are listed below for illustration. It should be noted here that the following embodiments use the element numbers and part of the contents of the previous embodiments, and the same numbers are used to represent the same or similar elements, and the description of the same technical contents is omitted. For the description of the omitted part, reference may be made to the foregoing embodiments, and no repetition is incorporated in the following embodiments.

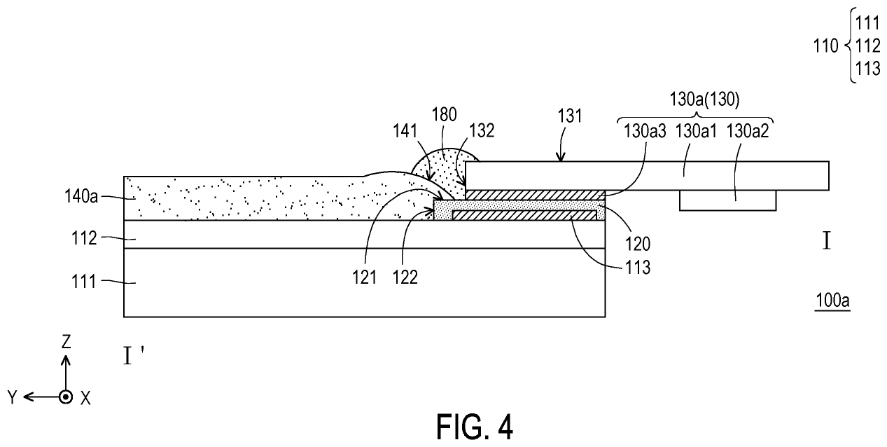

FIG. 4 is a schematic cross-sectional view of the electronic device of another embodiment of FIG. 1A taken along section line I-I′. Please refer to FIG. 1B and FIG. 4. The electronic device 100a of this embodiment is similar to the electronic device 100 of FIG. 1B, but the difference between the two is that the electronic device 100a of this embodiment further includes a second protective layer 180.

Specifically, referring to FIG. 4, in this embodiment, the first protective layer 140a is disposed on the conductive adhesive 120 to cover part of the conductive adhesive 120 and part of the circuit substrate 110. The second protective layer 180 is disposed on the driving element 130 to cover part of the driving element 130, part of the first protective layer 140a, and part of the conductive adhesive 120. In this embodiment, since the first protective layer 140a may cover and contact part of the top surface 121 and the lateral edge 122 of the conductive adhesive 120 (i.e., the lateral edge of the conductive adhesive 120 close to the first protective layer 140a) and the insulating layer 112 of the circuit substrate 110, and the second protective layer 180 may cover and contact part of the top surface 131 of the driving element 130, the lateral edge 132 of the driving element 130 (i.e., the lateral edge of the driving element 130 close to the first protective layer 140a) (including the lateral edge of the pad 130a3), part of the top surface 121 of the conductive adhesive 120, and the lateral edge 141 of the first protective layer 140a, it is possible to protect the conductive adhesive 120 and the pad 130a3 of the driving element 130, so as to reduce the intrusion of moisture and the corrosion of the connection pad 113 and the pad 130a, and the effect of blocking moisture may be achieved.

Additionally, by using the first protective layer 140a to cover and contact part of the top surface 121 and the lateral edge 122 of the conductive adhesive 120, and using the second protective layer 180 to cover and contact part of the top surface 131 of the driving element 130, the side edge 132 of the driving element 130, part of the top surface 121 of the conductive adhesive 120, and the lateral edge 141 of the first protective layer 140a, it is possible to improve the bonding strength of bonding the driving element 130 to the conductive adhesive 120, and improve the bonding strength of bonding the conductive adhesive 120 to the circuit substrate 110. That is, by disposing the first protective layer 140a and the second protective layer 180, the bonding strength of bonding the driving element 130 to the connection pad 113 (circuit substrate 110) may be improved, so that the driving element 130 and the connection pad 113 (or the circuit substrate 110) are not easily peeled off due to external force.

In this embodiment, since the driving element 130 is located in the non-display region 110b, the second protective layer 180 covering the driving element 130 does not need to have a high reflection effect. For example, the material of the second protective layer 180 may include silicon-based colloid, tuffy, other materials with moisture blocking effect or a combination of the foregoing, but the disclosure is not limited thereto.

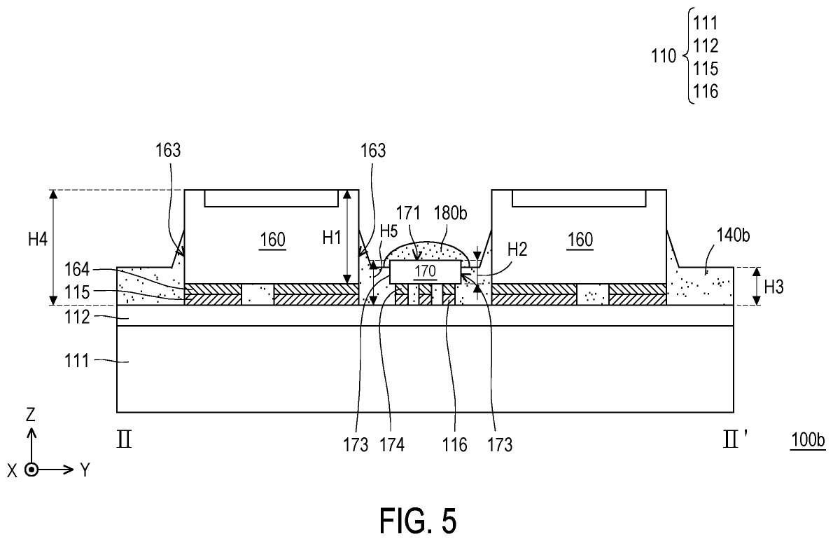

FIG. 5 is a schematic cross-sectional view of the electronic device according to another embodiment of FIG. 2A taken along section line II-II′. Please refer to FIG. 2B and FIG. 5 at the same time, the electronic device 100b of this embodiment is similar to the electronic device 100 of FIG. 2B, and the difference between the two is that the electronic device 100b of this embodiment further includes a second protective layer 180b.

Specifically, referring to FIG. 5, in this embodiment, the height H3 of the first protective layer 140b is less than the height H4 between the upper surface 161 of the first electronic unit 160 and the insulating layer 112 and is less than the height H5 between the upper surface 171 of the second electronic unit 170 and the insulating layer 112. The second protective layer 180b is disposed on the second electronic unit 170 to cover the part of the second electronic unit 170 exposed by the first protective layer 140b. In this embodiment, since the first protective layer 140b may at least surround part of the two side walls 163 of the first electronic unit 160 and part of the two side walls 173 of the second electronic unit 170, and the second protective layer 180b may cover the upper surface 171 of the second electronic unit 170 and another part of two side walls 173, it is possible to protect the connection pad 115 and the connection pad 116, thereby reducing the corrosion of the connection pad 115 (or the connection pad 116) caused by the intrusion of moisture, and the effect of blocking moisture may be achieved.

In this embodiment, by using the first protective layer 140 to surround and contact part of the two side walls 163 of the first electronic unit 160 (or part of the two side walls 173 of the second electronic unit 170), the pad 164 (or the pad 174), and the connection pad 115 (or the connection pad 116), it is possible to improve the bonding strength of bonding the first electronic unit 160 (or the second electronic unit 170) to the circuit substrate 110. That is, by disposing the first protective layer 140, the bonding strength of bonding the first electronic unit 160 (or the second electronic unit 170) to the connection pad 115 (the circuit substrate 110) may be improved, so that the first electronic unit 160 (or the second electronic unit 170) and the circuit substrate 110 are not easily peeled off due to external force.

In this embodiment, since the second electronic unit 170 is located in the display region 110a, the second protective layer 180b covering the second electronic unit 170 needs to have a high reflection effect. For example, the material of the second protective layer 180b may include silicone-based colloid, other materials with the effect of blocking moisture and improving reflectivity, or a combination of the foregoing, but not limited thereto. Furthermore, in this embodiment, since the second protective layer 180b has a high reflection effect, when the second electronic unit 170 is covered by the second protective layer 180b, the reflectivity of the second electronic unit 170 may be improved, and the occurrence of dark spots may be reduced. The reflectivity of the second protective layer 180b may be, for example, greater than or equal to 90%, but not limited thereto.

In some embodiments that are not shown, when the height of the first electronic unit is less than the height of the second electronic unit, the height of the first protective layer may also be less than or equal to the height between the upper surface of the first electronic unit and the insulating layer and less than the height between the upper surface of the second electronic unit and the insulating layer, and the second protective layer 180b may also cover the upper surface of the second electronic unit and another part of the two side walls.

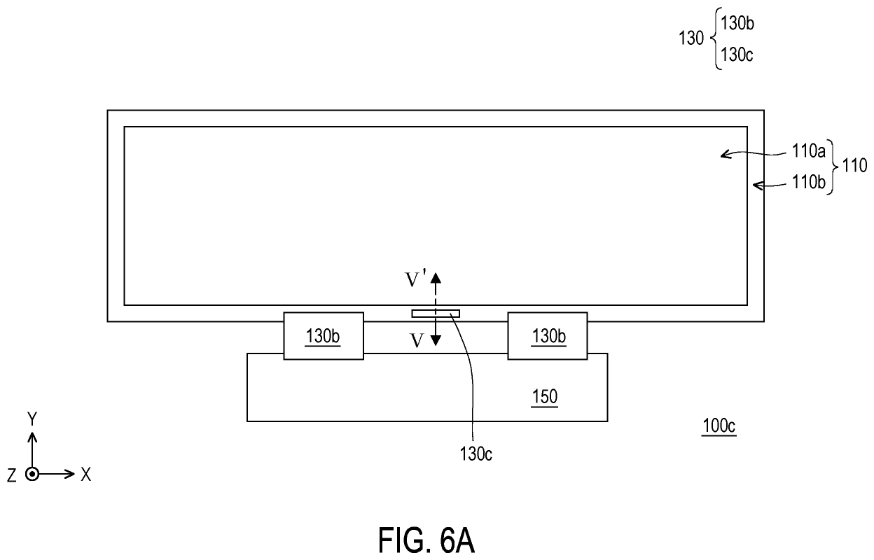

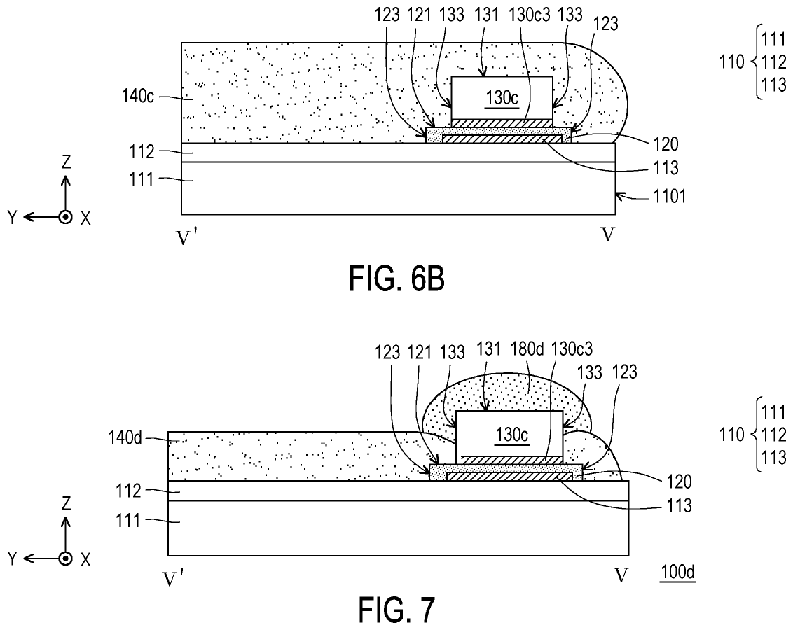

FIG. 6A is a schematic top view of an electronic device according to another embodiment of the disclosure. FIG. 6B is a schematic cross-sectional view of the electronic device of FIG. 6A taken along section line V-V′. For the clarity of the drawings and the convenience of description, FIG. 6A omits some elements in the electronic device 100c. Please refer to FIG. 1A, FIG. 1B, FIG. 6A and FIG. 6B at the same time. The electronic device 100c of this embodiment is similar to the electronic device 100 of FIG. 1A and FIG. 1B, and the difference between the two is that in the electronic device 100c of this embodiment, a chip-on-glass (COG) is used as the first driving element 130c to replace the chip-on-glass film in FIG. 1A.

Specifically, referring to FIG. 6A and FIG. 6B, in this embodiment, the first driving element 130c is located in the edge 1101 of the circuit substrate 110, and the first driving element 130c is completely overlapped with the circuit substrate 110 in the normal direction (i.e., the direction Z) of the circuit substrate 110.

The first protective layer 140c may at least surround the lateral edge 133 of the first driving element 130c and the lateral edge 123 of the conductive adhesive 120. In this embodiment, since the first protective layer 140c may cover and contact the top surface 131 of the first driving element 130c, the two lateral edges 133 of the first driving element 130c (including the lateral edge of the pad 130c3 of the first driving element 130c), a part of the top surface 121 of the conductive adhesive 120, the two lateral edges 123 of the conductive adhesive 120, and the insulating layer 112 of the circuit substrate 110, it is possible to protect the conductive adhesive 120 and the pad 130c3 of the driving element 130c, thereby reducing the corrosion of the connection pad 113 and the pad 130c3 caused by the intrusion of moisture, and the effect of blocking moisture may be achieved.

In some embodiments that are not shown, when the first protective layer covers and contacts two lateral edges of the first driving element, part of the top surface of the conductive adhesive, and two lateral edges of the conductive adhesive, and the first protective layer does not cover the top surface of the first driving element, it is also possible to reduce the corrosion of the connection pad and the pad caused by the intrusion of moisture, and the effect of blocking moisture may be achieved.

In some embodiments that are not shown, when the first protective layer covers and contacts part of the two lateral edges of the first driving element, part of the top surface of the conductive adhesive, and two lateral edges of the conductive adhesive, and the first protective layer does not cover the top surface of the first driving element and another part of the two lateral edges, it is also possible to reduce the corrosion of the connection pad and the pad caused by the intrusion of moisture, and the effect of blocking moisture may be achieved.

Moreover, by using the first protective layer 140c to cover and contact the top surface 131 of the first driving element 130c, the two lateral edges 133 of the first driving element 130c (including the lateral edge of the pad 130c3 of the first driving element 130c), part of the top surface 121 of the conductive adhesive 120, the two lateral edges 123 of the conductive adhesive 120, and the insulating layer 112 of the circuit substrate 110, it is possible to improve the bonding strength of bonding the first driving element 130c to the conductive adhesive 120, and improve the bonding strength of bonding the conductive adhesive 120 to the circuit substrate 110. That is to say, by disposing the first protective layer 140c, the bonding strength of bonding the first driving element 130c to the connection pad 113 (the circuit substrate 110) may be improved, so that the first driving element 130c and the connection pad 113 (or the circuit substrate 110) are not easily peeled off due to external force.

FIG. 7 is a schematic cross-sectional view of the electronic device according to another embodiment of FIG. 6A taken along section line V-V′. Please refer to FIG. 6B and FIG. 7 at the same time, the electronic device 100d of this embodiment is similar to the electronic device 100c of FIG. 6B, and the difference between the two is that the electronic device 100d of this embodiment further includes a second protective layer 180d.

Specifically, referring to FIG. 7, in this embodiment, the first protective layer 140d is disposed on the conductive adhesive 120 to cover part of the conductive adhesive 120, part of the first driving element 130c and part of the circuit substrate 110. The second protective layer 180d is disposed on the first driving element 130c to cover part of the first driving element 130c and part of the first protective layer 140d.

In this embodiment, since the first protective layer 140d may cover and contact part of the top surface 121 and the two lateral edges 123 of the conductive adhesive 120, the two lateral edges 133 of the first driving element 130c (including the lateral edge of the pad 130c3), and the insulating layer 112 of the circuit substrate 110, and the second protective layer 180d may cover and contact the top surface 131 and the two lateral edges 133 of the first driving element 130c, it is possible to protect the conductive adhesive 120 and the pad 130c3 of the first driving element 130c, so as to reduce the corrosion of the connection pad 113 and the pad 130c3 due to the intrusion of moisture, and the effect of blocking moisture may be achieved.

Furthermore, by using the first protective layer 140d to cover and contact part of the top surface 121 and the two lateral edges 123 of the conductive adhesive 120, the two lateral edges 133 of the first driving element 130c (including the lateral edge of the pad 130c3), and the insulating layer 112 of the circuit substrate 110, and using the second protective layer 180d to cover and contact the top surface 131 and the two lateral edges 133 of the first driving element 130c, it is possible to improve the bonding strength of bonding the first driving element 130c to the conductive adhesive 120, and improve the bonding strength of bonding the conductive adhesive 120 to the circuit substrate 110. That is to say, by disposing the first protective layer 140d and the second protective layer 180d, the bonding strength of bonding the first driving element 130c to the connection pad 113 (circuit substrate 110) may be improved, so that the first driving element 130c and the connection pad 113 (or the circuit substrate 110) are not easily peeled off due to external force.

In this embodiment, since the first driving element 130c is located in the non-display region 110b, the second protective layer 180d covering the first driving element 130c does not need to have a high reflection effect. For example, the material of the second protective layer 180d may include silicone-based colloid, tuffy, other materials with moisture blocking effect or a combination of the foregoing, but the disclosure is not limited thereto.

To sum up, in the electronic device of the embodiment of the present disclosure, since the first protective layer may cover part of the conductive adhesive, and the first protective layer (or the second protective layer) may cover part of the driving element, the conductive adhesive and the connection pad may be protected, so as to reduce the problem of corrosion of connection pad caused by intrusion of moisture, and the effect of blocking moisture may be achieved. In this embodiment, since the first protective layer has the effect of high reflection, when the first protective layer is used to cover part of the circuit substrate, the reflectivity of the circuit substrate may be improved, thereby improving the effective utilization of the light source. In this embodiment, since the first protective layer may at least surround part of both side walls of the first electronic unit and part of both side walls of the second electronic unit, and the first protective layer (or the second protective layer) may cover the upper surface of the second electronic unit, the connection pad may be protected, thereby reducing the problem of corrosion of the connection pad caused by intrusion of moisture, and the effect of blocking moisture may be achieved. In this embodiment, since the first protective layer may cover and contact the conductive wire (or test pad or alignment mark), the conductive wire (or test pad or alignment mark) may be protected, so as to reduce the corrosion of conductive wire (or test pad or alignment mark) caused by intrusion of moisture, and the effect of blocking moisture may be achieved.

Finally, it should be noted that the above embodiments are only used to illustrate the technical solutions of the present disclosure, but not to limit them. Although the present disclosure has been described in detail with reference to the foregoing embodiments, those of ordinary skill in the art should understand that: The technical solutions described in the foregoing embodiments can still be modified, or some or all of the technical features thereof can be equivalently replaced; and these modifications or replacements do not make the essence of the corresponding technical solutions deviate from the scope of the technical solutions of the embodiments of the present disclosure.

What is claimed is:

1. An electronic device, comprising:
a circuit substrate, comprising a connection pad;
a conductive adhesive, covering the connection pad;
a driving element, disposed on the connection pad, and electrically connected to the circuit substrate through the conductive adhesive; and
a first protective layer, covering a part of the conductive adhesive.

2. The electronic device according to claim 1, wherein there is a distance between a lateral edge of the conductive adhesive close to the first protective layer and a lateral edge of the driving element close to the first protective layer.

3. The electronic device according to claim 2, wherein the distance is greater than 0 mm and less than or equal to 5 mm.

4. The electronic device according to claim 1, wherein a reflectivity of the first protective layer is greater than or equal to 90%.

5. The electronic device according to claim 1, wherein a material of the first protective layer comprises a silicon-based colloid.

6. The electronic device according to claim 1, wherein the first protective layer further covers a part of the driving element.

7. The electronic device according to claim 1, further comprising:
a second protective layer, covering a part of the driving element.

8. The electronic device according to claim 7, wherein the second protective layer further covers a part of the first protective layer.

9. The electronic device according to claim 8, wherein the second protective layer further covers the part of the conductive adhesive.

10. The electronic device according to claim 1, wherein the first protective layer surrounds a lateral edge of the driving element.

11. An electronic device, comprising:
a circuit substrate;
a first electronic unit, which is arranged on the circuit substrate and has two side walls;
a second electronic unit, which is arranged on the circuit substrate and has two side walls, wherein the second electronic unit and the first electronic unit respectively have different functions; and
a first protective layer, which at least surrounds a part of the two side walls of the first electronic unit and a part of the two side walls of the second electronic unit.

12. The electronic device according to claim 11, wherein a reflectivity of the first protective layer is greater than or equal to 90%.

13. The electronic device according to claim 11, wherein a material of the first protective layer comprises a silicon-based colloid.

14. The electronic device according to claim 11, wherein the first electronic unit and the second electronic unit are electrically connected to each other through the circuit substrate.

15. The electronic device according to claim 11, wherein the second electronic unit has an upper surface, and the first protective layer further covers the upper surface.

16. The electronic device according to claim 11, wherein the second electronic unit has an upper surface, and the electronic device further comprises:
a second protective layer, which covers the upper surface.

17. The electronic device according to claim 11, wherein the circuit substrate further comprises a conductive wire, and the conductive wire is electrically connected to at least one of the first electronic unit and the second electronic unit.

18. The electronic device according to claim 17, wherein the first protective layer covers the conductive wire.

19. The electronic device according to claim 17, wherein the conductive wire comprises one of a signal line, a scan line, a data line, and a power line.

20. The electronic device according to claim 17, wherein the circuit substrate further comprises a test pad, the test pad is electrically connected to the conductive wire, and the first protective layer covers the test pad.
